(19) United States
(12) Patent Application Publication
(10) Pub. No.: US 2003/0048677 A1
(43) Pub. Date: Mar. 13, 2003

(54) Semiconductor device having a dual bus, dual bus system, shared memory dual bus system, and electronic instrument using the same

(75) Inventor: Hidehiro Muneno, Tsuchiura-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/237,095

(22) Filed: Sep. 9, 2002

(30) Foreign Application Priority Data
Sep. 11, 2001 (JP) 2001-274707

(51) Int. Cl. G11C 7/00

(52) U.S. Cl. 365/200

(57) ABSTRACT

A system LSI is connected with a first memory which is a bus slave connected to a low-speed bus and with a second memory which is another bus slave connected to a high-speed bus. The system LSI includes a first bus master which accesses to the first memory through the low-speed bus and a second bus master which accesses to the second memory through the high-speed bus. The first bus master can also access to the second memory through the low-speed bus. Thus, the second memory is shared by the first and the second bus masters.

Japanese Patent Application No. 2001-274707 filed on Sep. 11, 2001 is hereby incorporated by reference in its entirety.

### BACKGROUND OF THE INVENTION

This invention relates to a semiconductor device having a dual bus, dual bus system, shared memory dual bus system and electronic instrument using the same.

The semiconductor device called a system LSI comprises a CPU and various peripheral circuits all mounted on one chip. The system LSI of this kind is provided with a bus line, an external memory as a bus slave thereof is externally connected to the system LSI, and a plurality of bus masters sharing the external memory are arranged within the system LSI. One of the bus masters is a CPU, and the other bus masters are DMACs (Direct Memory Access Controllers) and the like.

In this case, with one bus line, where one of the bus masters is slow in operating speed, it is necessary to use a bus clock adapted to the slow speed of the bus master.

Also, while the one bus line is being exclusively occupied by one of the bus masters, the other bus masters are not allowed to operate. Thus, there has been a problem that system LSI performance does not improve, its speed being held down by a bus master slow in operating speed.

### BRIEF SUMMARY OF THE INVENTION

The present invention may provide a semiconductor device and dual bus system having a dual bus allowing a plurality of bus masters to simultaneously operate according to their respective operating speeds, and an electronic instrument using the same.

The present invention may also provide a semiconductor device and shared memory dual bus system allowing a plurality of bus masters to share at least one external memory, in which another bus master can simultaneously access another external memory while one of the bus masters is accessing that external memory, and an electronic instrument using same.

The invention may further provide a semiconductor device and shared memory dual bus system capable of carrying out a plurality of memory access requests to a shared external memory according to a priority processing criterion in the case there is competition between the requests, and an electronic instrument using same.

A semiconductor device according to one aspect of the invention comprises:

a low-speed bus enabling access to a first memory which is a bus slave in accordance with a low speed bus clock;

a high-speed bus enabling access to a second memory which is another bus slave in accordance with a high speed bus clock;

a first bus master which accesses to the first memory through the low-speed bus; and

at least one second bus master which accesses to the second memory through the high-speed bus.

According to the one aspect of the invention, the first or second bus masters are connected one of the low-speed bus and the high-speed bus according to their respective operation speeds. The first bus master can access the first memory through the low-speed bus, and the second bus master can access the second memory through the high-speed bus asynchronously with the first bus master. Accordingly, the first and second bus master can exclusively occupy the buses simultaneously. Moreover, the second bus master, compatible with high speed, can transfer data by a high-speed bus clock independently from speed-control of the low-speed bus clock.

The one aspect of the invention may further comprise an oscillator which generates the low-speed bus clock and the high-speed bus clock.

The semiconductor device according to this aspect may further comprise a memory controller which is connected to both the low-speed bus and the high-speed bus, and to the second memory, and carries out access control to the second memory according to a memory access clock. The memory controller may allow both the first bus master and the second bus master to access the second memory. In other words, the second memory is shared by the first and second bus masters.

The memory access clock used by the memory controller may be generated by an oscillator which generates the low-speed bus clock and the high-speed bus clock.

In the one aspect of the invention, the memory controller may give processing priority to a first memory access request inputted through the high-speed bus when the first memory access request competes with a second memory access request inputted through the low-speed bus.

Furthermore, the memory controller may give processing priority to a plurality of the first memory access requests inputted through the high-speed bus prior to processing the second memory access request inputted through the low-speed bus.

In this manner, the semiconductor device may further comprise:

a register which stores a priority processing criterion for giving processing priority by the memory controller to any one of a plurality of memory access requests; and

an update section which updates the priority processing criterion.

In order to realize the update section through software, a plurality of memory maps included in the first bus master may be used. In this case, the update section may define the priority processing criterion based on memory access frequency estimated according to one of the plurality of memory maps used by the first bus master, and may redefine the priority processing criterion each time the one of the memory maps being used is changed.

In order to configure the update section with hardware, the memory controller may have a register which stores the priority processing criterion. In this case, the update section may update the priority processing criterion based on a record of the memory access requests.

One example of such an update section may include:

a counter which counts the first memory access requests and the second memory access requests inputted within a reference time period; and

a criterion update section which updates the priority processing criterion based on an output from the counter.

The counter may count up one of the first and second memory access requests and may count down the other of the first and second memory access requests, and the counter may be reset for each reference time period. In this case, the criterion update section may update the priority processing criterion when the counter counts up or counts down a predetermined value.

As an index of the priority processing criterion, a parameter showing an attribute of data may be added to the data to be transferred over the low-speed bus and the high-speed bus. In this case, the memory controller may determine a processing order of the data based on the parameter in addition to the priority processing criterion.

One example of the parameter may be size of the data. The memory controller, in this case, may give processing priority to the data smaller in size.

Another example of the parameter may be a real-time processing rate of the data. In this case, the memory controller may give processing priority to the data with a higher real-time processing rate.

In the semiconductor device according to this aspect, at least one of the first memory and the second memory may be disposed in the semiconductor device. Alternatively, they may be externally connected.

In the semiconductor device according to this aspect, in the case that the second memory is provided outside the semiconductor device, the configuration may be made as follows. The memory controller may input and output N/2ⁿ bits of data (n is a natural number and N/2ⁿ is a multiple of 4) at one time to and from the second memory through N/2ⁿ terminals when the first bus master concurrently processes N bits. This can reduce the number of connection terminals to the second memory provided outside.

A dual bus system according to another aspect of the invention may be configured by connecting the first and second external memories to the semiconductor device having the dual bus.

An electronic instrument according to still another aspect of the invention may include the dual bus system.

A shared memory dual bus system according to still another aspect of the invention may be configured by connecting the first and second external memories to the semiconductor device having the shared memory dual bus system.

An electronic instrument according to yet another aspect may include the shared memory dual bus system.

### BRIEF DESCRIPTION OF THE SEVERAL VIEWS OF THE DRAWING

FIG. 1 is a schematic view of an e-mail phone as an example of an electronic instrument of the present invention;

FIG. 2 is a block diagram of a system LSI provided in the electronic instrument of FIG. 1;

FIG. 3 is a block diagram of an external memory controller of FIG. 2;

FIG. 4 is a flowchart illustrating the operation of the external memory controller of FIG. 2; and

FIG. 5 is a schematic diagram illustrating an example of a priority processing procedure in the case of competition between data in the external memory controller of FIG. 2.

### DETAILED DESCRIPTION OF THE EMBODIMENT

An embodiment of the present invention will now be described with reference to the drawings.

Electronic Instrument

The electronic instrument the present invention is to be applied is not dependent upon the field to which it will be applied, provided that it is mounted with a dual bus system or shared memory type dual bus system the details of which will be described later.

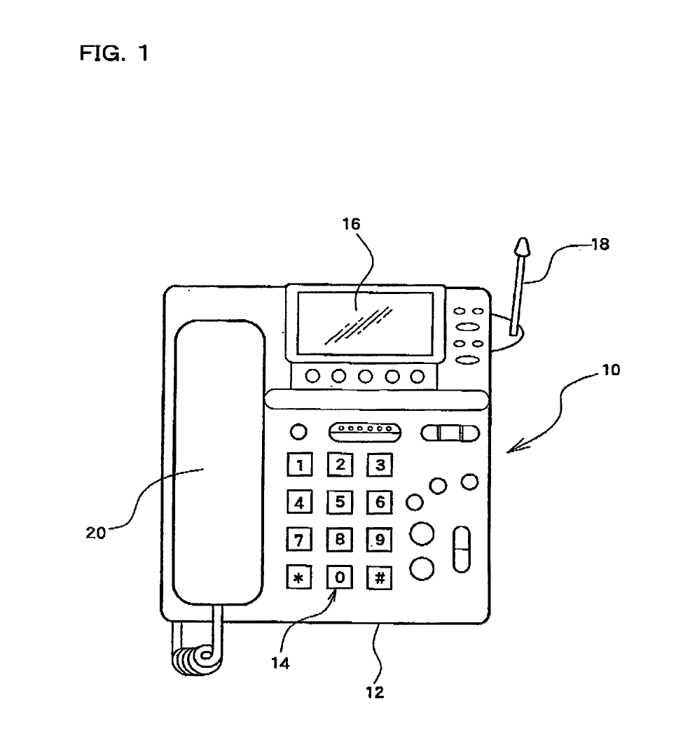

The electronic instrument of this kind includes, as one example, an e-mail phone 10 shown in FIG. 1. In FIG. 1, the e-mail phone 10 has, on a telephone main body 12, an operating section 14, a liquid-crystal display (LCD) 16, an antenna 18 and a handset 20. The operation input on the e-mail phone 10 is by inputting through various operation keys on the operating section 14. Besides, a touch panel on the LCD 16 can be utilized.

System LSI

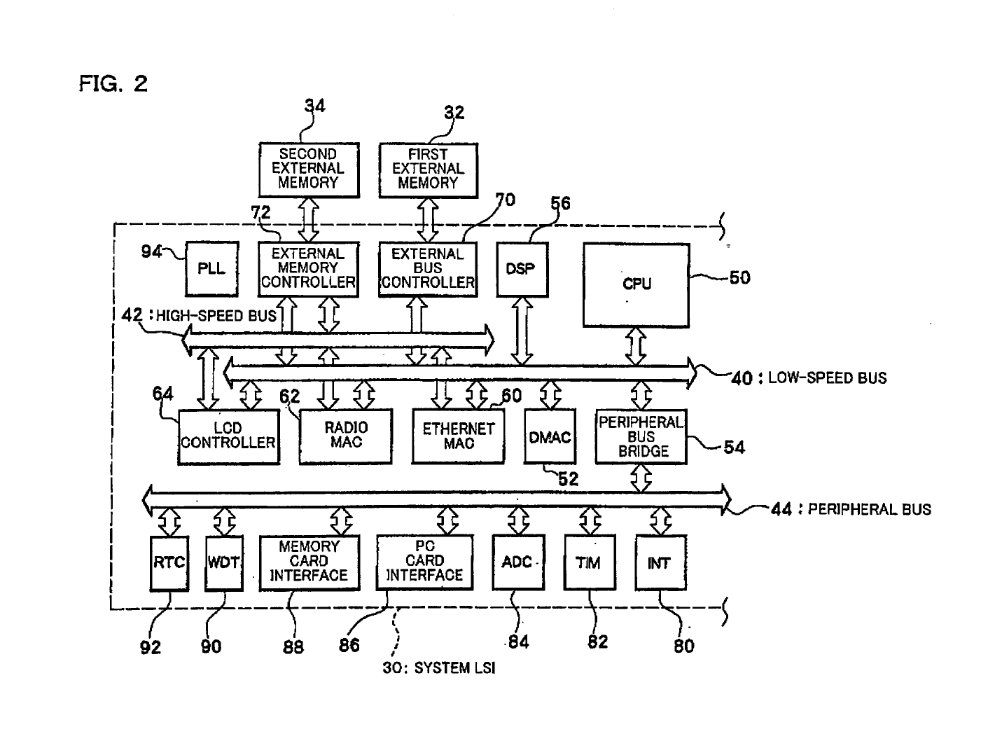

The electronic instrument 10 shown in FIG. 1 has mounted therein a system LSI 30, serving as its semiconductor device, a block diagram of which is shown in FIG. 2. The system LSI 30, called also a system-on-chip, has a CPU and peripheral circuits thereof made in one chip.

In FIG. 2, the system LSI 30 is connected, for example, with two external memories, i.e. a first external memory 32 for low-speed use and a second external memory 34 for high-speed use. The first external memory 32 uses an SRAM, a ROM or the like while the second memory 34, in this embodiment, uses an SDRAM (Synchronous Dynamic Random Access Memory), for example.

The system LSI 30 further comprises a low-speed bus 40 enabling access to the first external memory 32 which is a low-speed bus slave and a high-speed bus 42 enabling access to the second external memory 34 which is a high-speed bus slave. The bus clock for the low-speed bus 40 has a frequency, for example, of 33 to 66 MHz while the bus clock for the high-speed bus 42 has a frequency, for example, of 66 to 133 MHz, higher than that for the low-speed bus. A CPU 50 and DMAC (Direct Memory Access Controller) 52 are the bus master (first bus master) for the low-speed bus 40. The first bus master (CPU 50 and DMAC 52) can access the first external memory 32 which is the low-speed bus slave through the low-speed bus 40 and external bus controller 70.

The low speed bus 40 is further connected with a peripheral bus bridge 54. a DSP (Digital signal Processor) 56 and so on.

An Ethernet MAC (Media Access Controller) 60, radio MAC 62 and LCD controller 64 is provided as a bus master for the high-speed bus 42 (second bus master). The second bus master (Ethernet MAC 60. radio MAC 62 and LCD controller 64) can access the second memory 34 which is a high-speed bus slave through the high-speed bus 42 and external memory controller 72.

The second bus masters 60, 62 and 64 are also connected to the low-speed bus 40 so that data, addresses and commands can be exchanged between the second bus masters 60, 62 and 64 and the CPU 50.

The dual bus system thus configured allows one of the second bus masters 60, 62 and 64 to access the second external memory 34 through the high-speed bus 42 and external memory controller 72 while one of the first bus masters, e.g. CPU 50. is accessing the first external memory 32 through the low-speed bus 40 and external bus controller 70. Moreover, the second bus masters 60, 62 and 64 can implement data transmission on a high-speed bus clock independently from the speed-control by the low-speed bus clock of the low-speed bus 40, thus improving the performance of the system LSI 30.

Herein, the second bus masters 60, 62 and 64 are allowed to access only the second external memory 34 whereas the first bus masters 50 and 52 (possibly CPU 50 only) are allowed to access the first and second external memories 32 and 34.

In this case, a shared memory dual bus system is constructed in which the first and second bus masters share the second external memory 34.

The peripheral bus bridge 54 is connected with a peripheral bus 44. The peripheral bus 44 is connected with an interrupt controller (TNT) 80, a timer controller (TIM) 82, an analog/digital converter (ADC) 84, a PC card interface 86, a memory card interface 88, a watchdog timer (WDT) 90 and a real-time clock (RTC) 92.

In this manner, the provision of the peripheral bus 44 through the peripheral bus bridge 54 makes it possible to arrange the peripheral circuits of the CPU 50 on one chip.

In the system LSI 30, a phase locked loop (PLL) 94 is provided as an oscillator to generate various frequency clocks. The PLL 94 is to generate low-speed and high-speed bus clocks for the low-speed and high-speed buses 40 and 42. Furthermore, the PLL 94 also generates a memory access clock for use by the external memory controller 72, which point will be referred to later.

External Memory Controller

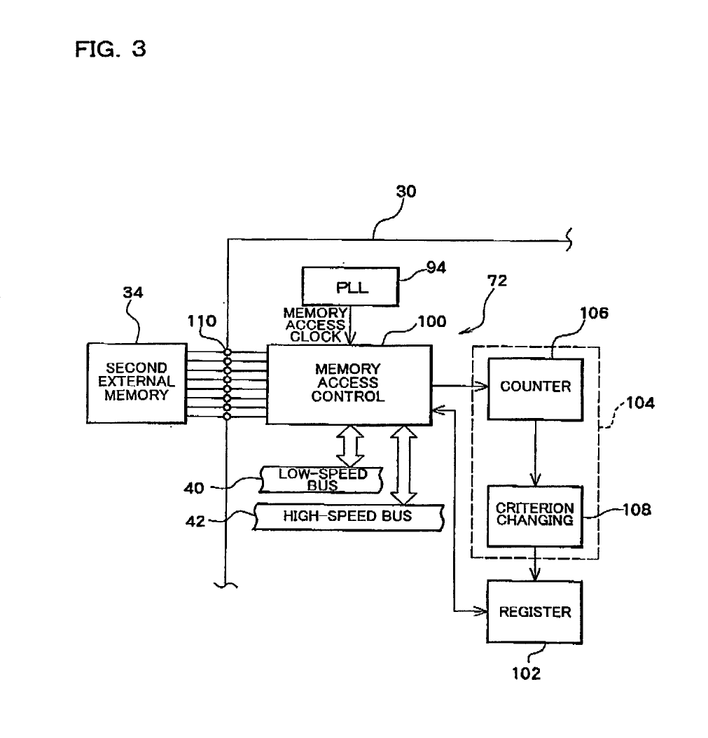

FIG. 3 is a block diagram of the external memory controller 72. In FIG. 3, the external memory controller 72 has a memory access control section 100, a register 102 and a register-content update circuit 104. The register-content update circuit 104 will be described later.

The memory access control section 100 directs the reading or writing of data from or to the second external memory 34 upon a memory access request inputted through the low-speed bus 40 or high-speed bus 42, according to a memory access clock from the PLL 94. Also, the memory access control section 100, in the case of competition between a plurality of memory access requests, processes them in the order dictated by the priority processing criterion previously stored in the register 102. The priority processing criterion stored in the register 102 can be updated by the register-content update circuit 104 based on a past record of memory access requests.

Operation of External Memory Controller

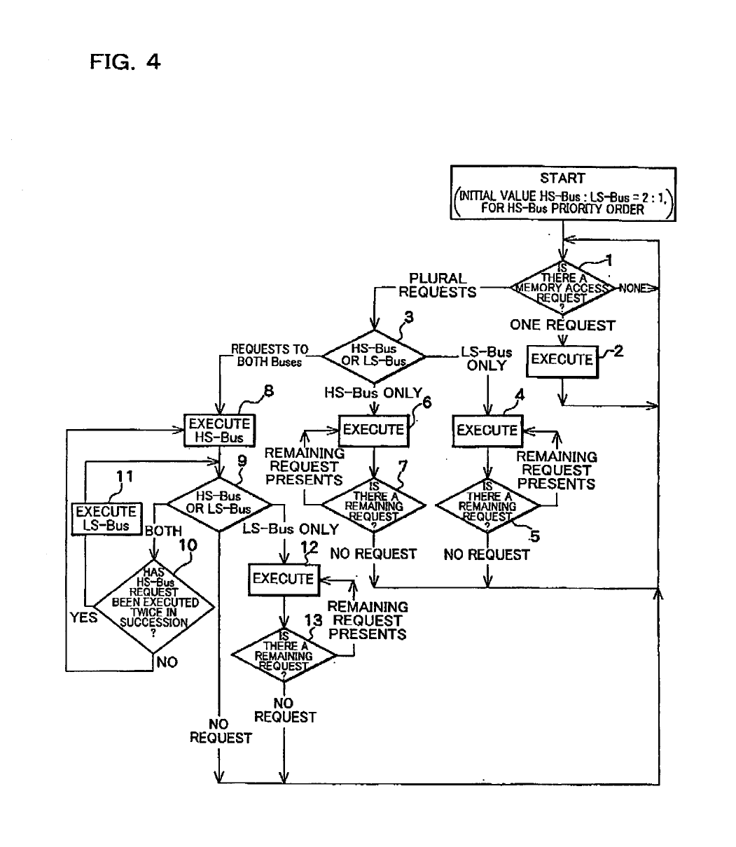

FIG. 4 is a flowchart for illustrating the operation to be made by the external memory controller 72 shown in FIGS. 2 and 3. This shows an example of dealing with a plurality of competing memory access requests according to the priority processing criterion.

The flowchart of FIG. 4 shows an example an initial value of the priority processing criterion stored in the register 102 shown in FIG. 3, the number of memory access requests through the high-speed bus 42 to be processed prior to processing one access request through the low-speed bus 40 (HS-Bus: LS-Bus=2:1) The initial-value ratio 2:1 may be set based on a ratio of high-speed bus clock frequency and low-speed bus clock frequency, for example.

In step 1 of FIG. 4, determination is made as to whether there was a memory access request to the external memory controller 72 or not, and further determination is made as to whether the request is one or a plurality. In a case that the memory access request is one, there is no competition between memory access requests. Accordingly, the memory access request may be executed in step 2.

In the case of a plurality of memory access requests in step 1 of FIG. 4, the memory access requests in plurality are separated according to type in step 3 of FIG. 4. First, in a case that all the memory access requests are inputted through the low-speed bus 40, one of the memory access requests inputted through the low-speed bus 40 is executed in step 4 of FIG. 4. In the next step 5, the answer to “are there remaining requests?” is always YES, and the process returns to step 4 to execute the remaining memory access requests. Thereafter, the steps 4 and 5 are repeated until the answer to “are there remaining requests?” is NO.

Herein, the criterion as to which memory access request priority is given among the plurality of memory access requests inputted through the low-speed bus 40, includes for example data size and data real-time processing rate.

Where there are six kinds of data sizes, for example, of 8, 16, 32, 64, 128 and 256 bits, the data size can be encoded with 3 bits which are provided on the memory access request at the beginning of this bit sequence. Also, data real-time processing rate is classified, for example, in 4 stages to be encoded with 2 bits, which are provided on the memory access request at the beginning of this bit sequence similarly to the data-size. For example, in the case there is interface between sound data and image data, the sound data is preferably given priority in processing. Accordingly, real-time processing rate is preferably set higher for the sound data than for the image data.

In the case there is competition between memory access requests as above, the external memory access controller 72 can determine the order of processing priority based upon the bit information on the data size and real-time processing rate encoded.

The order in processing priority may be such that, for example, priority is placed on the smaller size of data or on the higher real-time processing rate. The priority processing criterion can be stored in the register 102 shown in FIG. 3.

In step 3 of FIG. 4, in the case all the memory access requests are inputted through the high-speed bus 42, the memory access requests are executed, one by one, similarly to the above by using the steps 6 and 7 of FIG. 4. This process is repeated until the answer to “are there remaining requests?” is No. For the order of processing priority where there is competition between memory access requests inputted through the high-speed bus 42, determination can be similarly made depending, for example, upon data size or real-time processing rate as described above.

In another example of a priority processing criterion where there is competition between memory access requests inputted through high-speed bus 40, priority order may be set in advance based on which of the second bus masters 60, 62 and 64 is accessing.

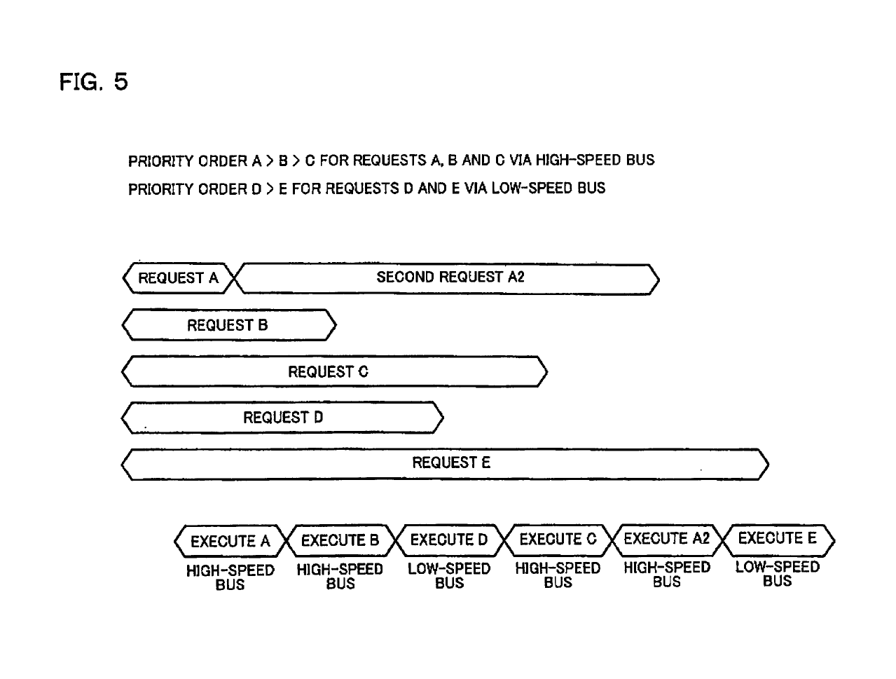

Description will be made here of the case, in step 3 of FIG. 4, that there is competition between memory access requests through the low-speed bus 40 and high speed bus 42. FIG. 5 shows a state of competition where memory access requests A to E (herein, A to E represent bus master types) are made nearly simultaneously in which, following a memory access request A, the next memory access request A2 has arrived from the same bus master.

In FIG. 5, it is assumed that the memory access requests A to C came via the high-speed bus 42 and the priority order is A, B and C based on data size and the like. The memory access requests D and E came via the low-speed bus 40 and the priority order is from D to E on the basis of data size and the like.

According to the priority processing criterion stored in the register 102 of FIG. 3, a memory access request inputted through the high-speed bus 40 is first selected in step 8 of FIG. 4, and the memory access request A is executed as the first priority order as noted above.

Next, in step 9 of FIG. 4, because there remain the memory access requests B to E and A2 inputted through the low-speed bus 40 and high-speed bus 42, the answer is “both”.

In step 10 of FIG. 4, because the answer to “Has Memory Access Request Inputted through High-speed Bus 40 been executed twice in succession?” is NO, the process returns to the step 8, to execute the memory access request B through the high-speed bus 40 as the second priority order.

In the following step 9, because there remain the memory access requests C to E and A2 inputted through the low-speed bus 40 and high-speed bus 42, the answer is “both”.

In the step 10 of FIG. 4, because the answer to “Has Memory Access Request Inputted through High-speed Bus 40 been executed twice in succession?.” is YES, the memory access request D through the low-speed bus 40 is executed as the third priority order in step 11.

In the following step 9, because there remain the memory access requests C, E and A2 inputted through the low-speed bus 40 and high-speed bus 42, the answer is “both”.

In the step 10 of FIG. 4, because the answer to “Has Memory Access Request Inputted through High-speed Bus 40 been executed twice in succession?” is NO, the process returns to the step 8 to execute the memory access request C through the high-speed bus 40 as the fourth priority order.

In the following step 9, because there remain the memory access requests E and A2 inputted through the low-speed bus 40 and high-speed bus 42, the answer is “both”.

Next, in the step 10 of FIG. 4, because the answer to “Has Memory Access Request Inputted through High-speed Bus 40 been executed twice in succession?” is NO, the process returns to step 8 to execute the memory access request A2 through the high-speed bus 40 as the fifth priority order.

In the following step 9, because there remains only the memory access requests E inputted through the low-speed bus 40, the memory access request E in step 12 is executed as the sixth priority order. In the next step 13, determination is made that there are no remaining memory access requests, and the process returns to step 1 to wait for the next memory access request.

In this manner, the order of execution is A, B, D, C. A2 and B.

Update of Priority Processing Criterion

The flowchart of FIG. 5 shows execution of a plurality of memory access requests competing with each other, based on a initial priority processing criterion value stored in the register 102 of FIG. 3.

This priority processing criterion can be updated depending, for example, upon the actual count of memory access requests, one example which is shown in FIG. 3.

The register-content update circuit 104 shown in FIG. 3 has a counter 106 and a criterion changing section 108. The counter 106 is to count the memory access requests inputted through the high-speed bus 42 and memory access requests inputted through the low-speed bus 40 inputted within a reference time period T. The counter 106 can be configured to count up either the access requests inputted through the high-speed bus or those through the low speed bus while counting down the other, to be furthermore reset at the end of every reference time period T.

This embodiment assumes that count-up (+1) is made each time there is a memory access request through the high-speed bus 42 within the reference time period T while countdown (−1) is made each time there is a memory access request through the low-speed bus 40 within.

In this case, when the counter 106 counts up to a predetermined value (e.g. +5) to cause overflow within the reference time period T, the reference update section 108 changes the ratio of executing memory access requests inputted through high-speed and low speed buses from its initial value 2:1 to 3:1. Also, when the counter 106 counts down to a predetermined value (e.g. −5) to cause underflow within the reference time period T, the reference update section 108 changes the execution ratio from its initial value 2:1 to 1:1.

In this manner, the priority processing criterion can be changed depending on the number of times of the memory accesses through the low-speed bus 40 or high-speed bus 42 within the reference time period T.

Updating the priority processing criterion like this may employ a software technique other than the above-noted hardware technique. In a software technique, the priority processing criterion setup in the external memory controller 72 is defined by a program from the CPU 50. The memory map in the CPU 50 can be used, for example. The CPU 50 possesses in advance a plurality of memory maps prepared for each of application software to be executed. In each memory map is defined a memory assignment to be used upon executing each application software. Consequently, based on each of executing application software, it is possible to presume the frequency of accesses of the CPU 50 to the second external memory 34 which is the main memory. The CPU 50 redefines the priority processing criterion, e.g. to be 2:1, 3:1 and 4:1 by a program, based on the presumed frequency of memory accesses, and the priority processing criterion for use in the external memory controller 72 can be changed by this program.

In this manner, an Ethernet MAC 60 or the like connected to a network includes periods in which large amount of data is dealt with and periods in which data is not handled at all, in contrast to LCD controller 64 which periodically deals with data during the display period of the LCD 16. In this manner, by changing the priority processing criterion depending on the situation, the optimal processing can be realized in each situation.

The invention is not limited to the foregoing embodiment but can be modified in various ways within the scope of the gist of the invention.

For example, where the first bus master (e.g. CPU 50) concurrently processes N bits, the external memory controller 72 may be configured to input and output data in the amount of N/2ⁿ bits (n is a natural number and N/2ⁿ is a multiple of 4) at one time period to and from the second external memory 34 through N/2ⁿ terminals.

Specifically, there may be 32 bits processed by the CPU 50. In this case, a total of 32 bits of data can be inputted/outputted by sending 8 bits at a time by the use of burst transfer or the like, through 8 terminals (32/4=8 when n=2) (terminal 110 shown in FIG. 3), repeated four times. Or else, if n=1, a total of 32 bits of data can be inputted/outputted by sending 16 bits at a time through 16 terminals (32/2=16), repeated twice. By thus narrowing, for example, a 32-bit data width to 8 bits, 16 bits or the like, it is possible to reduce the number of the data input/output terminals provided on the system LSI.

Meanwhile, although the foregoing embodiment describes the configuration using the first and second external memories, this is a configuration adapted for facilitating memory exchange. Differently from this, it is possible to adopt a configuration arranging the first and second memories within a semiconductor device or a configuration arranging either the first or second memories within the semiconductor device and the other the outside the semiconductor device.

What is claimed is:

1. A semiconductor device comprising;
a low-speed bus enabling access to a first memory which is a bus slave in accordance with a low speed bus clock;
a high-speed bus enabling access to a second memory which is another bus slave in accordance with a high speed bus clock;
a first bus master which accesses to the first memory through the low-speed bus; and
at least one second bus master which accesses to the second memory through the high-speed bus.

2. The semiconductor device as defined in claim 1, further comprising an oscillator which generates the low-speed bus clock and the high-speed bus clock.

3. The semiconductor device as defined in claim 1, further comprising a memory controller which is connected to both the low-speed bus and the high-speed bus, and to the second memory, and carries out access control to the second memory according to a memory access clock,
wherein the memory controller allows both the first bus master and the second bus master to access the second memory.

4. The semiconductor device as defined in claim 3, further comprising an oscillator which generates the low-speed bus clock, the high-speed bus clock and the memory access clock.

5. The semiconductor device as defined in claim 3,
wherein the memory controller gives processing priority to a first memory access request inputted through the high-speed bus when the first memory access request competes with a second memory access request inputted through the low-speed bus.

6. The semiconductor device as defined in claim 5,
wherein the memory controller gives processing priority to a plurality of the first memory access requests inputted through the high-speed bus prior to processing the second memory access request inputted through the low-speed bus.

7. The semiconductor device as defined in claim 5, further comprising:
a register which stores a priority processing criterion for giving processing priority by the memory controller to any one of a plurality of memory access requests; and
an update section which updates the priority processing criterion.

8. The semiconductor device as defined in claim 7,
wherein the first bus master has a plurality of memory maps, and
wherein the update section defines the priority processing criterion based on memory access frequency estimated according to one of the plurality of memory maps used by the first bus master, and redefines the priority processing criterion each time the one of the memory maps being used is changed.

9. The semiconductor device as defined in claim 7,
wherein the memory controller has a register which stores the priority processing criterion, and
wherein the update section updates the priority processing criterion based on a record of the memory access requests.

10. The semiconductor device as defined in claim 9,
wherein the update section includes:
a counter which counts the first memory access requests and the second memory access requests inputted within a reference time period; and
a criterion update section which updates the priority processing criterion based on an output from the counter.

11. The semiconductor device as defined in claim 10,
wherein the counter counts up one of the first and second memory access requests and counts down the other of the first and second memory access requests, and the counter is reset for each reference time period, and
wherein the criterion update section updates the priority processing criterion when the counter counts up or counts down a predetermined value.

12. The semiconductor device as defined in claim 3,
wherein a parameter showing an attribute of data is added to the data to be transferred over the low-speed bus and the high-speed bus, and
wherein the memory controller determines a processing order of the data based on the parameter in addition to the priority processing criterion.

13. The semiconductor device as defined in claim 12,
wherein the parameter is size of the data, and
wherein the memory controller gives processing priority to the data smaller in size.

14. The semiconductor device as defined in claim 12.
wherein the parameter is a real-time processing rate of the data, and
wherein the memory controller gives processing priority to the data with a higher real-time processing rate.

15. The semiconductor device as defined in claim 1,
wherein at least one of the first memory and the second memory are disposed in the semiconductor device.

16. The semiconductor device as defined in claim 3,
wherein the second memory is provided outside the semiconductor device, and
wherein the memory controller inputs and outputs N/2ⁿ bits of data (n is a natural number and N/2ⁿ is a multiple of 4) at one time to and from the second memory through N/2ⁿ terminals when the first bus master concurrently processes N bits.

17. A dual bus system comprising:
the semiconductor device having the low-speed bus and the high-speed bus as defined in claim 1;
a first external memory to be accessed through the low-speed bus of the semiconductor device; and
a second external memory to be accessed through the high-speed bus of the semiconductor device.

18. An electronic instrument having a dual bus system as defined in claim 17.

19. A shared memory dual bus system comprising;
the semiconductor device having the low-speed bus, the high-speed bus and the memory controller as defined in claim 3;
a first external memory to be accessed through the low-speed bus of the semiconductor device; and
a second external memory to be accessed through the low-speed bus and the high-speed bus of the semiconductor device and the memory controller.

20. An electronic instrument having the shared memory dual bus system as defined in claim 19.
